(19) United States
(12) Patent Application Publication
(10) Pub. No.: US 2012/0006387 A1
(43) Pub. Date: Jan. 12, 2012

(54) MOISTURE-PROOF FILM, METHOD FOR MANUFACTURING THE SAME, BACK SHEET FOR SOLAR CELL MODULE AND SOLAR CELL MODULE USING THE SAME

(75) Inventor: Hitoshi Adachi, Kanagawa (JP)

(73) Assignee: Konica Minolta Opto, Inc., Hachioji-shi (JP)

(21) Appl. No.: 13/257,625

(22) PCT Filed: Feb. 1, 2010
(86) PCT No.: PCT/JP2010/051338

§ 371 Date: Sep. 20, 2011

(30) Foreign Application Priority Data
Mar. 27, 2009 (JP) 2009-078721

(51) Int. Cl. H01L 31/048; B05D 3/02; B05D 5/00; B32B 5/16; B32B 27/18

(52) U.S. Cl. 136/251; 428/323; 428/331; 428/329; 428/328; 427/372.2

(57) ABSTRACT

Disclosed are: a moisture-proof film in which an inorganic oxide layer is formed by coating with high productivity and which has excellent moisture-proof performance compared to conventional deposition or sputtering procedures; a process for producing the moisture-proof film; a back sheet for a solar cell module and a solar cell module, which comprise the moisture-proof film. The moisture-proof film comprises a resin base and a moisture-proof layer arranged on the resin base, wherein the moisture-proof layer comprises a coating film comprising an inorganic oxide film containing inorganic oxide particles having an average particle diameter of 1 nm to 1 μm inclusive.

### TECHNICAL FIELD

The present invention relates to a moisture-proof film which is excellent in productivity and moisture-proof properties, the method for manufacturing the same, a back sheet for a solar cell module using the same, and a solar cell module.

### BACKGROUND TECHNOLOGY

Heretofore it has been known that, in a moisture-proof film using a synthetic resin base material, a vapor-deposited film is applied as a moisture-proof layer.

The formation of the vapor-deposited film is selected from optional methods such as a vacuum-deposition method (a physical vapor deposition, or a chemical vapor deposition) which has previously been applied, or a spattering method.

On the other hand, there exists a sol-gel method as a method for forming a coating film comprising an inorganic oxide by a coating by which a high productivity can be obtained, and examples applied to a moisture-proof film have been known (refer, for example, to Patent Document 1).

In addition, it has been known an example of forming a silica-based film in which siloxanepolymer, which is derived from hydrolytic condensate of alkoxysilane, is applied to a substrate, which is then heated at a low temperature (refer to Patent Document 2).

On the other hand, heretofore, it was a significant problem that, in the solar cell module, the cell is subjected to an aged deterioration due to water vapor penetration, and thereby, the power generation efficiency decreases. The issue of the water vapor penetration can be solved by sandwiching the module between upper and lower glasses, but in general a resin-made moisture-proof sheet (a back sheet) is used on the back side in view of reduction of weight, cost, or the like. However, water vapor penetration properties of the current resin-made moisture-proof sheet is insufficient, and there were some cases that the solar cell module degrades without waiting for twenty years which is a standard of durability required for the solar cell module.

On the other hand, in the conventional resin-made moisture-proof sheet, a method for forming an inorganic oxide film such as silica is generally taken by a vapor deposition (refer, for example, to Patent Documents 3 and 4). However, since the vapor deposition step requires larger production equipment such as a vacuum apparatus, and is not suitable for continuous production, the vapor deposition step had a high cost problem.

As a method for forming an inorganic oxide layer by coating, a sol-gel method has heretofore been known, but since it requires a high temperature to sinter the film into ceramics, the method had a problem to cause damage to the resin base material.

### PRIOR ARTS

### Patent Documents

Patent Document 1: Japanese Patent Application Publication No. 2008-179104
Patent Document 2: Japanese Patent Application Publication No. 2007-254677
Patent Document 3: Japanese Patent Application Publication No. 2006-334865
Patent Document 4: Japanese Patent Application Publication No. 2008-105381

### SUMMARY OF THE INVENTION

### Problem to be Solved by the Invention

The present invention has been achieved in consideration of the above problems and situations, and an objective to solve the problem is to provide a moisture-proof film which forms an inorganic oxide layer with high productivity by coating and has excellent moisture-proof properties compared to conventional vapor deposition or sputtering, and to provide a manufacturing method thereof. Further, the objective is to provide a back sheet for a solar cell module using the aforesaid moisture-proof film, and a solar cell module using it.

### Measures to Solve the Issues

The above problems relating to the present invention will be solved by the following means.

Item 1. A moisture-proof film in which a moisture-proof layer is arranged on a resin base material, wherein the aforesaid moisture-proof layer is composed of a coating film including an inorganic oxide film containing inorganic oxide particles having an average particle diameter of 1 nm or more and 1 μm or less.

Item 2. The moisture-proof film described in the above Item 1, wherein the above inorganic oxide particles include at least one compound among silicon oxide, aluminum oxide, zinc oxide, titanium oxide, and zirconium oxide.

Item 3. A manufacturing method of a moisture-proof film for manufacturing the moisture-proof film described in the above Item 1 or Item 2, wherein the method comprises a step of forming a coating film by applying a compound having a polysiloxane structure and a dispersion containing inorganic oxide particles onto a resin base material, and a step of forming an inorganic oxide film containing inorganic oxide particles by heating the aforesaid coating film at a heating temperature of 50° C. or more and 200° C. or less.

Item 4. A back sheet for a solar cell module wherein the aforesaid moisture-proof film described in the above Item 1 or Item 2 is used.

Item 5. A solar cell module wherein the moisture-proof film described in the above Item 1 or Item 2 is used for a back sheet.

### EFFECTS OF THE INVENTION

According to the above means of the present invention, it is possible to provide a moisture-proof film which forms an inorganic oxide layer with high productivity by coating and has excellent moisture-proof properties compared to conventional vapor deposition or sputtering, and to provide a manufacturing method thereof. It is further possible to provide a back sheet for a solar cell module using the aforesaid moisture-proof film, and a solar cell module using it.

### BRIEF DESCRIPTION OF THE DRAWINGS

FIG. 1 is a schematic flow sheet showing an embodiment of the manufacturing apparatus of a film-shaped resin base material.

FIG. 2 is a cross-sectional view showing an example of a layer structure of the back sheet for the solar cell module.

FIG. 3 is a cross-sectional view showing an example of the solar cell module manufactured by using the above back sheet.

FIGS. 4a and 4b are cross-sectional views showing examples of layer structure of the back sheet for the solar cell.

### MODE FOR CARRYING OUT THE INVENTION

The moisture-proof film of the present invention is a moisture-proof film in which a moisture-proof layer is arranged on a resin base material, which is characterized in that the aforesaid moisture-proof layer is composed of a coating film comprising an inorganic oxide film incorporating inorganic oxide particles having the average particle diameter of 1 nm or more and 1 μm or less. This characteristic is a technological characteristic common to the inventions claimed in claims 1 to 5.

As an embodiment of the present invention, it is preferable that the above inorganic oxide particles incorporate at least one compound among silicon oxide, aluminum oxide, zinc oxide, titanium oxide, and zirconium oxide from a view point of appearance of the effect of the present invention.

The method for manufacturing the moisture-proof film of the present invention is preferably a mode having a step of forming a coating film by applying a compound having a polysiloxane structure and a dispersion containing inorganic oxide particles onto a resin base material, and a step of forming an inorganic oxide film containing inorganic oxide particles by heating the aforesaid coating film at a heating temperature of 50° C. or more and 200° C. or less.

The moisture-proof film of the present invention can be suitably used as a back sheet for a solar cell module. Therefore, there can be provided a solar cell module in which the aforesaid moisture-proof film being excellent in moisture-proof properties is used as a back sheet.

Hereinafter, the present invention and the constitutional elements thereof, and modes or the like to implement the present invention will be detailed.

(Resin Base Material)

As the resin base material relating to the present invention, conventionally known various kinds of resin films may be used. For example, included are polyester film such as cellulose ester series film, polyester series film, polycarbonate series film, polyarylate series film, polysulfone (including polyethersulfone) series film, polyethylene terephthalate, polyethylene naphthalate; and included are polyethylene film, polypropylene film, cellophane, cellulose diacetate film, cellulose triacetate film, cellulose acetate propionate film, cellulose acetate butyrate film, polyvinylidene chloride film, polyvinylalcohol film, ethylene vinylalcohol film, syndiotactic polystyrene series film, polycarbonate film, norbornene series resin film, polymethyl pentene film, polyether ketone film, polyether ketoneimide film, polyamide film, fluorine resin film, nylon film, polymethyl methacrylate acryl film. Among them, preferred are polycarbonate series film, polyester series film, norbornene series resin film, and cellulose ester series film.

It is particularly preferable to use polyester series film, or cellulose ester series film, and the resin base material may be a film manufactured by a melt flow casting or solution flow casting film forming method.

The aforesaid resin base material preferably has a suitable thickness according to the kind of resin, purpose or the like. For example, the thickness is, in general, within a range of 10 to 300 μm, preferably 20 to 200 μm, and more preferably 30 to 100 μm.

The method for manufacturing the resin base material will be described later.

(Moisture-Proof Layer)

The moisture-proof film of the present invention is characterized in that at least one surface of the resin base material is provided with a moisture-proof layer. Further, the aforesaid moisture-proof layer is characterized in that it is composed of a coating film comprising an inorganic oxide film containing inorganic oxide particles having an average particle diameter of 1 nm or more and 1 μm or less.

The moisture-proof layer relating to the present invention is designed to prevent degradation, due to moisture change, in particular due to high humidity, of the resin base material, various functional elements and the like which are protected by the aforesaid resin base material, but may have a special function or usage, and then, moisture-proof layers of various modes can be arranged as long as it maintains the above characteristics.

As the moisture-proof properties of the moisture-proof film of the present invention, the moisture-proof properties of the aforesaid moisture-proof layer is preferably controlled so that water vapor permeability at 40° C. and 90% RH becomes 100 g/m²·24 hr/μm or less, preferably 50 g/m²·24 hr/μm or less, and more preferably 20 g/m²·24 hr/μm or less.

(Inorganic Oxide Particles)

The composition of the inorganic oxide particles relating to the present invention is not limited to a specific one, but is preferably any one of silicone oxide, aluminum oxide, zinc oxide, titanium oxide, and zirconium oxide.

The average particle diameter is 1 nm or more and 1 μm or less, preferably 3 nm or more and 300 nm or less, and more preferably 5 nm or more and 100 nm or less. In general, a strong coating film cannot be obtained only by heat treatment of a coating film obtained from a dispersion of inorganic oxide particles of μm-order size, but since the inorganic oxide particles to be used are particles of nm-order size like the present invention, the reactivity increases as specific surface area increases, and then, strong inorganic oxide can be formed by heat treatment. On the other hand, it is difficult to obtain the inorganic oxide particles having particle diameter of less than 1 nm themselves, and at the same time, even if it is obtained, coagulation among particles develops in a short time. Therefore, the above particles are extremely unstable, and it was difficult to apply them to the present invention.

(Inorganic Oxide Film Incorporating Inorganic Oxide Particles)

The inorganic oxide film relating to the present invention incorporates, as its constitutional elements, at least the above inorganic oxide particles and a compound having a polysiloxane structure to form a silica-based film described below.

The content percentage of the inorganic oxide particles is preferably 30% in volume or more and 99% in volume or less, and more preferably 50% in volume or more and 80% in volume or less.

The content percentage of the inorganic oxide particles in the inorganic oxide film is given by a percentage of the total area of inorganic particles contained in the total cross-section of the inorganic oxide film by observing the cross-section of the film via the transmission electron microscope. Since the original particle interfaces of the inorganic particles can be observed in the film, it is possible to determine the quantity of an area where the inorganic particles are present. The inorganic oxide film can be formed by a dry process such as vapor deposition or a wet process such as a sol-gel method, but, since particle interfaces of crystals are present in any film formed by the above process, barrier properties against gas or water vapor were insufficient. However, since generation of cracks which cause deterioration of barrier properties can be minimized by incorporating the inorganic oxide particles in the inorganic oxide film relating to the present invention, it has become possible to improve the barrier properties.

(Compound Having Polysiloxane Structure)

As the compound having a polysiloxane structure relating to the present invention, conventionally known various compounds can be used, but a siloxane polymer is preferably used.

The siloxane polymer relating to the present invention is not limited to a specific one, and a polymer having a Si—O—Si bond. Among these siloxane polymers, a hydrolytic condensate of alkoxysilane may be suitably used. As the above alkoxysilane, all kinds of alkoxysilane can be used. Such kind of alkoxysilane includes compounds represented by the following Formula (a).

R¹ₙ—Si(OR²)₄₋ₙ Formula (a)

wherein R¹ is hydrogen, an alkyl or allyl group having a carbon number of 1 to 20, R² is a monovalent organic group, and n is an integer of 0 to 2.

The monovalent organic group includes, for example, an alkyl group, an aryl group, an allyl group, and glydyl group. Among them, an alkyl group and an aryl group are preferable. The carbon number of the alkyl group is preferably 1 to 5, and the example includes a methyl group, an ethyl group, a propyl group, and a butyl group. The alkyl group may be linear or branched, and hydrogen atom may be substituted by fluorine. The carbon number of the aryl group is preferably 6 to 20, and the example includes a phenyl group, and a naphthyl group.

The specific examples represented by the above Formula (a) are as follows:

(a1) in the case of n=0, included are tetramethoxysilane, tetraethoxysilane, tetrapropoxysilane, and tetrabuthoxysilane;

(a2) in the case of n=1, included are monoalkyltrialkoxysilane such as monomethyltrimethoxysilane, monomethyltriethoxysilane, monomethyltripropoxysilane, monoethyltrimethoxysilane, monoethyltriethoxysilane, monoethyltripropoxysilane, monopropyltrimethoxysilane, and monopropyltriethoxysilane; monophenyltrialkoxysilane such as monophenyltrimethoxysilane, and monophenyltriethoxysilane;

(a3) in the case of n=2, included are dialkyldialkoxysilane such as dimethyldimethoxysilane, dimethyldiethoxysilane, dimethyldipropoxysilanc, diethyldimethoxysilane, diethyldiethoxysilane, diethyldipropoxysilane, dipropyldimethoxysilane, dipropyldiethoxysilane, and dipropyldipropoxysilane; diphenyldialkoxysilane such as diphenyldimethoxysilane, and diphenyldiethoxysilane.

In the silica based film forming composite, a weight-average molecular weight of siloxane polymer is preferably 200 or more and 50,000 or less, and more preferably 1,000 or more and 3,000 or less. As long as the weight-average molecular weight is within this range, coating properties of the silica based film forming composite can be allowed to improve.

The hydrolytic condensation of alkoxysilane can be obtained by allowing alkoxysilane, which serves as a polymerizable monomer, to react under presence of acid catalyst or base catalyst in an organic solvent. The alkoxysilane, which serves as a polymerizable monomer, may be used individually, or may be condensed by combining a plurality thereof.

Further, trialkylalkoxysilane such as trimethylmethoxysilane, trimethylethoxysilane, trimethylpropoxysilane, triethylmethoxysilane, triethylethoxysilane, triethylpropoxysilane, tripropylmethoxysilane, and tripropylethoxysilane; triphenylalkoxysilane such as triphenylmethoxysilane, and triphenylethoxysilane; or the like may be added during hydrolysis.

The degree of hydrolysis of alkoxysilane, which is a presupposition of the condensation, can be controlled by the amount of water to be added, and, in general, the amount is preferably 1.0 to 10.0 times by mole of the total moles of alkoxysilane represented by the above Formula (a), and it is more preferable to add the water with a ratio of 1.5 to 8.0 times by mole. By making the amount of water to be added 1.0 times or more by mole, the degree of the hydrolysis can be made sufficiently large, to result in an excellent film formation. On the other hand, by making it 10.0 times or less by mole, gelation can be prevented, and thereby, preservation stability can be improved.

In addition, in the condensation of alkoxysilane represented by Formula (a), an acid catalyst is preferably used. The acid catalyst to be used is not limited to a specific one, and any of conventionally used organic or inorganic acid can be used. The organic acid includes an organic carboxylic acid such as acetic acid, propionic acid, and butyric acid, and the inorganic acid includes hydrochloric acid, nitric acid, sulfuric acid, phosphoric acid, and the like. The acid catalyst may be directly added to a mixture of alkoxysilane and water, or may be added to alkoxysilane as an acidic aqueous solution with water.

The hydrolysis reaction is usually completed in about 5 to 100 hours. Also, it is possible to complete the reaction in a shorter time by allowing for the reaction through adding aqueous solution drops of acid catalyst to an organic solvent containing at least one alkoxysilane represented by Formula (a), at a heating temperature between a mom temperature and a temperature not exceeding 80° C. The hydrolyzed alkoxysilane thereafter causes a condensation reaction to form a network of Si—O—Si as a result.

<<Method for Forming Silica-Based Film>>

As the method for forming a silica-based film, first, a silica-based film forming composite is applied on a substrate. As a method for applying a silica-based film forming composite on a substrate, there may be used an optional method such as, for example, a spray method, a spin coat method, a dip coat method, and a roll coat method, but usually a spin coat method is used.

Next, the silica-based film forming composite applied on a substrate is subjected to a heat treatment. The heat treatment is not particularly limited in its means, temperature, time, or the like, but usually above composite may be heated for about 1 minute to about 6 minutes on a hot plate at about 80° C. to about 300° C.

According to the silica-based film forming composite of the present invention, acid or base is generated when heated by heat treatment. Since the hydrolysis is accelerated by the generated acid or base, an alkoxy group is changed into a hydroxyl group to form alcohol. After that, since Si—O—Si network is formed by condensation of two alcohol molecules, a compact silica-based film can be obtained by the heat treatment.

Further, the heat treatment is preferably carried out by increasing temperature in three stages or more. Specifically, under atmosphere or under an inert gas atmosphere such as nitrogen, the first heat treatment is carried out on a hot plate at about 60° C. to about 150° C. for about 30 seconds to about two minutes, and after that, the second heat treatment is carried out at about 100° C. to about 220° C. for about 30 seconds to about two minutes, and further, the third heat treatment is carried out at about 150° C. to about 300° C. for about 30 seconds to about two minutes. By carrying out the heat treatment in three stages or more, preferably in about three to six stages, the silica-based film can be formed at a lower temperature.

(Heat Treatment Step)

The moisture-proof film of the present invention is a moisture-proof film in which a moisture-proof layer is arranged on a resin base material, and characterized in that the aforesaid moisture-proof film was fanned by heat treatment of the coating film composed of a dispersion containing the above inorganic oxide particles.

With regard to the temperature of the heat treatment in the present invention, in the case where the surrounding base material has a high heat resistance property, heat treatment at higher temperature is essentially preferable in terms of reduction of treatment time. However, from the point of view of using a synthetic resin as the base material in the moisture-proof film of the present invention, the temperature is preferably 50° C. or more and 200° C. or less, and more preferably, 70° C. or more and 150° C. or less.

As the healing method, any commonly used one can be applied, and a heating method of repeating a short time heating intermittently is also preferably used.

As the healing method, it is preferable that the moisture-proof layer is formed by performing local heating of the coating film (also referred to as a coated layer) of the dispersion containing inorganic oxide particles.

The term “local heating” of the coating film means to heat substantially a coated layer (at higher temperature than the resin base material by 10° C. or more, preferably by 20° C. or more) without substantially degrading the resin base material by heating. As the local heating method to achieve this, various conventionally known methods can be adopted. For example, heating using an infrared heater, a hot wind, microwave, ultrasonic wave heating, induction heating, or the like can be appropriately selected. Among them, intermittent irradiation of infrared rays, electromagnetic waves such as microwave, or ultrasonic wave is preferably used.

As the irradiation method of infrared rays, an irradiation apparatus such as an infrared lamp, and an infrared heater is usable. Irradiation by the infrared-ray irradiation apparatus may be carried out at one time as long as the inorganic oxide layer can be formed, but, in order to heat locally the coated layer, a method for repeating unit time infrared-ray irradiation intermittently is preferably used. The method for repeating short-time infrared-ray irradiation intermittently includes, for example, a method for repeating on and off of the infrared-ray irradiation apparatus for a short time, a method for repeating the irradiation by moving a shielding plate which is arranged between the infrared-ray irradiation apparatus and a non-irradiated body, and a method for repeating the infrared-ray irradiation by transporting an irradiated body (a resin film) with infrared-ray irradiation apparatuses being arranged at a plurality of places in the transporting direction of the irradiated body.

Microwave is the general term for UHF to EHF bands of a frequency of 1 GHz to 3 THz and a wavelength of about 0.1 mm to about 300 mm, and a microwave generator with a frequency of 2.45 GHz is commonly used, but a microwave with a frequency of 1 to 100 GHz may be used. Example includes a microwave irradiator with 2.45 GHz (μ-Reactor, manufactured by Shikoku instrumentation Co., Ltd.), and a microwave generator (a magnetron) which irradiates a microwave of 2.45 GHz.

In the present patent application, the term “ultrasonic wave” indicates an elastic oscillating wave of a frequency of 10 kHz or more (a sound wave). As the heating method by the ultrasonic wave relating to the present invention, it is preferable to repeat short-time heating intermittently in a similar way to the infrared-ray irradiation with a horn frequency in a range of 50 kHz or less.

Also in the case of heating a coated layer using a microwave or an ultrasonic wave, by repeating short-time heating intermittently in a similar way to the infrared-ray irradiation, a method for heating only a resin base material locally without causing degradation of the resin base material is preferably used.

(Synthetic Resin Layer)

In the present invention, it is preferable to arrange not only the above moisture-proof layer but a synthetic resin layer. It is a purpose of the synthetic resin layer relating to the present invention that the above moisture-proof layer obtains a function as a stress relaxation layer so that the above moisture-proof layer causes no crack due to bending of a moisture-proof film, or a function as an antifouling layer to prevent the original moisture-proof properties from deteriorating due to the moisture-proof layer being stained.

As a material composing the synthetic resin layer, conventionally known various synthetic resins can be used. Examples include polyester such as polyethylene terephthalate (PET), and polyethylene naphthalate (PEN); cellulose esters or derivatives thereof such as polyethylene, polypropylene, cellophane, cellulose diacetate, cellulose triacetate (TAC), cellulose acetate butyrate, cellulose acetate propionate (CAP), cellulose acetate phthalate, and cellulose nitrate; a cycloolefin-based resin such as polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polysulfones, polyetherketoneimide, polyamide, fluorine resin, nylon, polymethyl methacrylate, acryl or polyarylates, ARTON (a trade name, manufactured by JSR Corporation), or APEL (a trade name, manufactured by Mitsui Chemicals).

Of these resins, a cycloolefin-based resin is particularly preferred. The cycloolefin-based resin (hereinafter also referred to as “cyclic olefin-based resin”) includes norbornene-based resin, monocyclic cyclo (cyclic) olefin-based resin, cyclo (cyclic) conjugated diene-based resin, vinyl alicyclic hydrocarbon-based resin, and hydrogenated compounds thereof. Among them, norbornene-based resin may be suitably used due to its excellent transparency and formability.

The norbornene-based resin includes, for example, a ring-opening polymer of a monomer having a norbornene structure or a ring-opening copolymer between a monomer having a norbornene structure and another monomer, or hydrogenated products thereof, and an addition polymer of a monomer having a norbornene structure or an addition polymer between a monomer having a norbornene structure and another monomer, or hydrogenated products thereof.

Among them, a hydrogenated compound of a ring-opening (co)polymer of a monomer having a norbornene structure is particularly suitably used from the viewpoint of transparency, formability, heat resistance, low hygroscopicity, dimensional stability, lightweight properties, and the like.

The monomer having a norbornene structure includes bicyclo[2.2.1]hepto-2-en (a common name: norbornene), tricyclo[4.3.0.1^{2,5}]deca-3,7-diene (a common name: dicyclopentadiene), 7,8-benzotricyclo[4.3.0.1^{2,5}]deca-3-en (a common name: methanotetrahydrofluorene), tetracyclo[4.4.0.1^{2,5}.1^{7,10}]dodeca-3-en (a common name: tetracyclododecene), and derivatives of these compounds (for example, those having a substitute group in the ring). The substitute groups include, for example, an alkyl group, an alkylene group, a polar group, and the like. Also, a plurality of the same or different substitute groups may bond to a ring. The monomer having a norbornene structure can be used alone or in combination of two or more.

The polar group includes heteroatom or atom group having a heteroatom. The heteroatom includes, for example, oxygen atom, nitrogen atom, sulfur atom, silicon atom, halogen atom and the like. Specific examples of the polar group include a carboxyl group, a carbonyloxycarbonyl group, an epoxy group, a hydroxyl group, an oxy group, an ester group, a silanol group, a silyl group, an amino group, a nitrile group, a sulphone group and the like.

Other monomers capable of ring-opening copolymerization with a monomer having a norbornene structure include monocyclo (cyclic) olefins such as cyclohexene, cycloheptene and cyclooctene, and their derivatives; cyclo (cyclic) conjugated diene such as cyclohexadiene and cycloheptadiene, and their derivatives.

The ring-opening polymer of a monomer having a norbornene structure and the ring-opening copolymer of a monomer having a norbornene structure and another monomer capable of copolymerization can be obtained by (co)polymerizing the monomer in the presence of a heretofore known ring-opening polymerization catalyst.

Other monomers capable of addition copolymerization with a monomer having a norbornene structure include, for example, α-olefin with 2 to 20 carbon atoms such as ethylene, propylene and 1-butene, and their derivatives; cycloolefin such as cyclobutene, cyclopentene and cyclohexene, and their derivatives; and unconjugated diene such as 1,4-hexadiene, 4-methyl-1,4-hexadiene and 5-methyl-1,4-hexadiene, and the like. These monomers can be used alone or in combination of two or more. Among them, α-olefin is preferable, and ethylene is more preferable.

The addition polymer of a monomer having a norbornene structure and the addition copolymer of a monomer having a norbornene structure and another monomer capable of copolymerization may be obtained by polymerizing the monomer in the presence of a heretofore known addition polymerization catalyst.

The hydrogenated products of the ring-opening polymer of a monomer having a norbornene structure, the hydrogenated products of the ring-opening copolymer of a monomer having a norbornene structure and another monomer capable of ring-opening copolymerization therewith the hydrogenated products of the addition polymer of a monomer having a norbornene structure, and the hydrogenated products of the addition copolymer of a monomer having a norbornene structure and another monomer capable of addition copolymerization therewith, can be obtained by adding a heretofore known hydrogenation catalyst containing a transition metal such as nickel and palladium in a solution of the above polymer and by hydrogenating the carbon-carbon unsaturated bonds to preferably 90% or more.

Among the norbornene-based resins, preferable are those having X: bicyclo[3.3.0]octane-2,4-diyl-ethylene structure, and Y: tricyclo[4.3.0.1^{2,5}]decane-7,9-diyl-ethylene structure as the repeating unit, with contents of their repeating units being 90% by mass or more of the entire repeating unit of the norbornene-based resin, and a ratio between the X content and the Y content being 100:0 to 40:60 m mass ratio of X:Y.

The molecular weight of the cyclo (cyclic) olefin resin used in the present invention is suitably selected in accordance with the intended use. The polyisoprene or polystyrene converted weight average molecular weight (Mw) measured by gel permeation chromatography using cyclohexane as the solvent (or toluene if polymer resin is not dissolved) is usually 20,000 to 150,000, preferably 25,000 to 100,000, or more preferably 30,000 to 80,000. If the weight average molecular weight is within such ranges, the mechanical strength and formability of the film is highly balanced, and appropriate.

The glass transition temperature of the cyclo (cyclic) olefin resin may be suitably selected in accordance with the intended use. It is preferably in the range of 130 to 160° C., and more preferably in the range of 135 to 150° C.

The specific example of the above cycloolefin-based resin used in the present invention includes, for example, ARTON (a trade name, manufactured by JSR Corporation), ZEONOR (a trade name, manufactured by Zeon Corporation), and ESSINA (a trade name, manufactured by Sekisui Chemical Co., Ltd.).

Into each layer, in particular, into the base material of the moisture-proof film of the present invention, there may be added, if needed, a filler, an antioxidant, an ultraviolet absorber, a heat stabilizer, a lubricant, an antistatic agent, an antibacterial agent, a pigment, and the like.

(Method for Manufacturing Resin Base Material for Moisture-Proof Film)

As the method for manufacturing a resin base material used for the moisture-proof film of the present invention, usable are manufacturing methods such as an ordinary inflation method, a T-die method, a calender method, a cutting method, a flow casting method, an emulsion method, a hot-press method and the like, but, from the viewpoint of inhibition of coloring, inhibition of defects caused by foreign substance, inhibition of optical defects such as a die line, a solution flow casting method or a melt flow casting method by a flow casting method is preferable.

Hereinafter, as a typical example, a manufacturing method in the case of production as a film-shaped resin base material will be described in details.

<Method for Manufacturing Resin Base Material by Solution Flow Casting Method>

(Organic Solvent)

In the case where the resin base material relating to the present invention is manufactured by a solution flow casting method, any useful organic solvent to prepare a dope can be used without limitation as long as the organic solvent dissolves a thermoplastic resin such as a cellulose ester resin.

For example, a chlorine organic solvent includes methylene chloride, and a non-chlorine organic solvent includes methyl acetate, ethyl acetate, amyl acetate, acetone, tetrahydrofuran, 1,3-dioxolane, 1,4-dioxan, cyclohexanone, ethyl formate, 2,2,2-trifluoroethanol, 2,2,3,3-hexafluoro-1-propanol, 1,3-difluoro-2-propanol, 1,1,1,3,3,3-hexafluoro-2-methyl-2-propanol, 1,1,1,3,3,3-hexafluoro-2-propanol, 2,2,3,3,3-pentafluoro-1-propanol, nitroethane, ethyl lactate, lactic acid, and diacetone alcohol, and preferably usable are methylene chloride, methyl acetate, ethyl acetate, acetone; ethyl lactate and the like.

In the dope, there may be incorporated, other than the above organic solvents, a linear or branched aliphatic alcohol having the number of carbon atoms of 1 to 4 in 1 to 40% by mass. When the ratio of the alcohol in the dope becomes higher, the web turns into a gel to result in easy separation from a metal support. When the ratio of the alcohol is less, the alcohol has a role to accelerate dissolution of thermoplastic resin in a non-chlorine organic solvent system.

In particular, preferable is a dope composite in which a total of at least 10 to 45% by mass of the thermoplastic resin is dissolved in a solvent containing methylene chloride and a linear or branched aliphatic alcohol having carbon number of 1 to 4.

The linear or branched aliphatic alcohol having the number of carbon atoms of 1 to 4 includes methanol, ethanol, n-propanol, iso-propanol, n-butanol, sec-butanol, and tert-butanol. Among them, ethanol is preferable due to high stability of dope, relatively low boiling point, excellent drying characteristics and the like.

Hereinafter, the preferable film-forming method of the film-shaped resin base material relating to the present invention (hereinafter, also simply referred to as a “film”) will be described.

1) Dissolution Step

The dissolution step is one in which thermoplastic resin and other additives are dissolved in an organic solvent composed of mainly a favorable solvent for thermoplastic resin while stirring in a dissolving vessel to form a dope.

For dissolving the thermoplastic resin, various dissolving methods can be used, such as a method of performing the dissolution under ordinary pressure, a method of performing the dissolution below the boiling point of the main solvent, a method for performing the dissolution above the boiling point of the main solvent with applying pressure, a method of performing with a cooling dissolving method as described in Japanese Patent Application Publication Nos. H9-95544, H9-95557, or H9-95538, and a method for performing the dissolution under high pressure as described in Japanese Patent Application Publication No. H11-21379, but, in particular, the method for performing the dissolution above the boiling point of the main solvent with applying pressure is preferable.

Return scrap is a finely pulverized film, and means both sides of a film which were cut out, or an off-spec original fabric for the film due to scratches or the like, which is generated when the film is formed. The return scrap is also reused.

2) Flow Casting Step

The flow casting step is one in which a dope is conveyed to a pressure die through a solution sending pump (for example, a pressure type metering gear pump), and is cast from a slit of the pressure die onto a flow casting position of a metal support such as an endless metal belt which moves infinitely, for example a stainless steel belt, or a rotating metal drum.

Preferable is the pressure die in which the slit shape at the mouth piece portion can be regulated and the layer thickness is readily controlled to be uniform. The pressure die includes a coat hanger die, and a T-die, and any of these may be favorably employed. The surface of the metal support is a mirror plane. In order to increase the film forming speed, two or more pressure dies may be provided on the metal support, and dopes in which the quantity of the dope may be divided into two or more may be superimposed. Or, a laminated structure film is preferably prepared by a co-casting method in which a plurality of dopes are simultaneously cast.

3) Solvent Evaporation Step

The solvent evaporation step is one in which a web (a dope is cast onto a flow-casting support and the formed dope film is called a web) is heated on a flow-casting support to evaporate a solvent.

In order to evaporate the solvent, there are several methods which include a method in which air is blown from the web side, and/or a method in which heat is transferred through liquid from the back surface of the support, and a method in which heat is transferred from the front and back surfaces by radiation heat. Among them, a heat transfer method by liquid from the back surface is preferable due to high drying efficiency. Further, a method of combining these methods is preferably used. It is preferable to dry the web on the support, which was formed on the support after casting, under atmosphere of 40 to 100° C. In order to maintain the web under atmosphere of 40 to 100° C., it is preferable to blow warm air having this temperature on the upper surface of the web or to heat the web by means of infrared rays or the like.

The aforesaid web is preferably peeled off from the support within 30 to 120 seconds from the viewpoint of surface quality, moisture permeability, and a peeling property.

4) Peeling Step

The peeling step is one in which a web whose solvent has been evaporated on the metal support is peeled at a peeling position. The peeled web is sent to the next step.

The temperature at the peeling position on the metal support is preferably 10 to 40° C., and more preferably 11 to 30° C.

At the time of peeling, the residual amount of solvent in the web at the time of peeling on the metal support is preferably in the range of 50 to 120% by mass depending on the degree of drying, the length of the metal support, and the like. In the case where the peeling is carried out at the time when the residual amount of solvent is larger, if the web is excessively soft, flatness at peeling is lost and wrinkles or streaks due to peeling tension is likely to be generated. Therefore, the residual amount of solvent at the time of peeling is determined by balancing economical speed and quality.

The residual amount of solvent of the web is defined by the formula below.

Residual amount of solvent (%)=(mass of web before heating treatment−mass of web after heating treatment)/(mass of web after heating treatment)×100

The heat treatment when measuring residual amount of solvent indicates heat treatment at 115° C. for one hour.

Peeling tension when peeling film from a metal support is commonly 196 to 245 N/m. However, in the case where wrinkles tend to result during peeling, it is preferable to peel at a tension of 190 N/m or less, and further, it is preferable to peel at a tension from the lowest tension capable of peeling to 166.6 N/m, more preferably to peel at a tension from the lowest tension to 137.2 N/m, and it is particularly preferable to peel at a tension from the lowest tension to 100 N/m.

In the present invention, temperature at the peeling position on the aforesaid metal support is preferably regulated to −50 to 40° C., more preferably to 10 to 40° C., and most preferably to 15 to 30° C.

5) Drying and Stretching Step

After peeling, the web is dried using dryer 35 in which the web is conveyed by alternately passing through a plurality of rollers installed in the dryer, and/or tenter stretching apparatus 34 in which the web is conveyed while clipping both edges of the web with clips.

As common drying means, heated air is blown onto both surfaces of the web, but means in which heating is carried out via application of microwaves instead of air flow are also available. Excessively rapid drying tends to deteriorate flatness of the finished film. High temperature drying is preferably carried out when the residual solvent is about 8% by mass or less. Throughout the entire process, the drying is carried out at about 40° C. to about 250° C., and in particular preferably carried out at 40 to 160° C.

When a tenter stretching apparatus is used, it is preferable to use an apparatus which enables independent control of the film holding length (the distance from the holding initiation to the holding termination) by the left and right holding means of the tenter. Further, during the tentering step, to improve flatness, it is preferable to intentionally provide zones which differ in temperature.

Further, it is also preferable to provide a neutral zone between temperature different zones so that adjacent zones cause no interference.

Stretching operation may be carried out with the operation being divided into multiple stages, and it is preferable to carry out biaxial stretching in the flow casting direction as well as in the lateral direction. Further, when biaxial stretching is carried out, simultaneous biaxial stretching may be carried out, or it may be carried out in a stepwise fashion.

In the above case, the term “in a stepwise fashion” refers, for example, to a process in which it is possible to carry out sequential stretching which differs in stretching direction or in which it is possible to divide the stretching of the same direction into multiple steps and to add stretching in another direction in any of the steps. Namely, for example, the following stretching steps are possible.

Stretching in the flow casting direction—stretching in the lateral direction—stretching in the flow casting direction—stretching in the flow casting direction

Stretching in the lateral direction—stretching in the lateral direction—stretching in the flow casting direction—stretching in the flow casting direction

Further, simultaneous biaxial stretching also includes a case in which stretching is carried out in one direction and tension in another direction is relaxed to allow contraction. Stretching ratio of simultaneous biaxial stretching is preferably in the range of 1.01 to 1.5 times in the lateral and longitudinal directions.

When tentering is carried out, the residual amount of solvent in a web is preferably 20 to 100% by mass at the initiation of tentering, and it is preferable that until the residual solvent in the web reaches 10% by mass or less, drying is carried out while tentering, and more preferably 5% by mass or less.

Drying temperature when tentering is carried out is preferably 30 to 160° C., more preferably 50 to 150° C., and most preferably 70 to 140° C.

In the tentering step, in view of enhancement of film uniformity, it is preferable that temperature distribution in the lateral direction in the ambience is small. The temperature distribution in the lateral direction in the tentering step is preferably within ±5° C., more preferably within ±2° C., and most preferably within ±1° C.

6) Winding Step

The winding step is one in which, after the residual amount of solvent in the web reaches 2% by mass or less, the resulting web is wound by winder 37 as a film. By allowing the residual amount of solvent to be 0.4% by mass or less, a film having excellent dimensional stability can be obtained. It is particularly preferable to wind the film at 0.00 to 0.10% by mass.

As a winding method, commonly used methods may be used and include a constant torque method, a constant tension method, a tapered tension method, and a program tension control method of constant internal stress. Any of these may be appropriately selected and used.

The film relating to the present invention is preferably a long-size film, which length specifically indicates about 100 m to about 5,000 m, and it is usually provided in a roll shape. Further, the film width is preferably 1.3 to 4 m, and more preferably 1.4 to 2 m.

The film thickness of the film relating to the present invention is not particularly limited, but is preferably 20 to 200 μm, more preferably 25 to 150 μm, and particularly preferably 30 to 120 μm.

<Method for Manufacturing Resin Base Material by Melt Flow Casting Film Forming Method>

A method for manufacturing the resin base material relating to the present invention, as a film-shaped resin base material, by a melt flow casting film forming method will be described.

<Manufacturing Step of Melting Pellets>

Composite used for melt extrusion, which composes a film comprising thermoplastic resin is preferably usually pelletized in advanced by kneading.

Pelletization may be made by publicly known methods, and is made, for example, in such a way that composite composed of dried thermoplastic resin and various additives is supplied to an extruder by a feeder, kneaded using a uniaxial or biaxial extruder, which is then extruded in a strand form from a die, cooled with water or air, and cut.

It is important to dry the raw materials before carrying out extrusion to prevent decomposition of the raw materials. Since cellulose ester particularly tends to absorb moisture easily, it is desirable to dry it at 70 to 140° C. for three hours or more using a dehumidification hot air dryer or a vacuum dryer so that the moisture percentage is made 200 ppm or less, more preferably 100 ppm or less.

Additives may be supplied to an extruder, or may be supplied respectively by respective feeders. A small amount of additives such as an antioxidant may be preferably mixed in advance in order to mix it uniformly.

In the mixing of the antioxidant, the antioxidant may be mixed as solids to each other. Alternatively, the antioxidant may be dissolved in a solvent, if necessary, and then mixed by being impregnated in thermoplastic resin, or by being sprayed.

A vacuum NAUTA MIXER or the like may be preferable, because it can carry out drying and mixing simultaneously. Moreover, when the pellets may touch with air at the outlet of a feeder section or a die, it is desirable to make the place under atmosphere such as dehumidified air or dehumidified N₂ gas.

It is preferable to suppress the shearing force of an extruder and to process at a temperature capable of pelletizing as low as possible in order to avoid the deterioration of resin (the decrease of a molecular weight, coloring gel formation, and the like). For example, in the case of a biaxial extruder, it is preferable to rotate them in the same direction by the use of a deep groove type screw. In the viewpoint of the homogeneity in kneading, an engagement type is preferable.

The film formation is performed by use of the pellets obtained as above. It is also possible to supply the powder of a raw material without pelletizing it to an extruder with a feeder, and to carry out film formation by using it.

<Extrusion Step of Molten Mixture from Die to Cooling Roll>

First, the prepared pellets are, after foreign matters having been eliminated by filtering through a leaf disc type filter or the like, co-extruded in a film form from a T-die using a uniaxial or biaxial type extruder at melting temperature Tm during extrusion of about 200 to 300° C., solidified on a cooling roll, and then, flow cast while pressing with an elastic touch roll.

On introduction into extruder from a supply hopper, it is preferable to prevent oxidative decomposition or the like under vacuum, or under a reduced pressure or in inert gas atmosphere. The Tm is a temperature at the outlet of die of the extruder.

A defect of a streak form may be generated when a flaw is caused on a die or a foreign matter such as coagulum of plasticizer is adhered on a die. Such a defect is also called as a die line, and it is preferable to make a structure having a stagnant portion of resin as small as possible in a pipe from an extruder to a die to surface defects such as a die line. It is preferable to use a die having as minimum flaws as possible in the interior and on a lip of a die.

The inner surface of an extruder or a die which comes in contact with molten resin is preferably subjected to a surface treatment so that the molten resin is hard to adhere to the inner surface by decreasing the surface roughness or by utilizing a material having a low surface energy. Specific example includes those having been subjected to hard chromium plating or ceramic thermal spraying and having been ground to make a surface roughness of 0.2 S or less.

In the present invention, the cooling roll is not particularly limited, but is a high rigidity metal roll, which is provided with a structure inside such that a temperature controllable heat medium or coolant flows. The size is not limited as long as it is sufficiently large so as to cool the melt-extruded film, and the diameter of the cooling roll is usually about 100 mm to about 1 m.

The surface material of the cooling roll includes carbon steel, stainless steel, aluminum, and titanium. Further, it is preferable that the cooling roll is subjected to surface treatment such as hard chromium plating, nickel plating, amorphous chromium plating, or ceramic thermal spraying, in order to increase surface hardness or to improve peeling property from resin.

The surface roughness of the cooling roll is preferably 0.1 μm or less in Ra, and more preferably 0.05 μm or less in Ra. The more smooth the roll surface is, the more smooth the obtained film surface is. Of course, it is preferable that the surface having been subjected to the surface treatment is further ground to the above surface roughness.

In the present invention, as an elastic touch roll, usable is a silicon rubber roll whose surface is covered by a thin metal sleeve, as described in Japanese Patent Application Publication Nos. H3-124425, H8-224772, H7-100960, H10-272676, WO97/028950, Japanese Patent Application Publication Nos. H11-235747, 2002-36332, 2005-172940, or 2005-280217.

When the film is peeled from the cooling roll, film deformation is preferably prevented by controlling tension.

<Stretching Step>

In the present invention, the film obtained by the above manner can further be stretched at least in one direction 1.01 to 3.0 times after the film passed through a step in which the film is in contact with the cooling roll.

The film is preferably stretched in each of both longitudinal direction (the film conveying direction) and lateral direction (width direction) by 1.1 to 2.0 times.

As the stretching method, a publicly known roll stretching machine or tenter can be preferably used. In particular, in the case where the moisture-proof film doubles as a polarizing plate protection film, laminating with a polarizing film in a roll form can be preferably carried out by stretching the film in the width direction.

Since the film was stretched in the width direction, the slow axis of the film becomes aligned in the width direction.

In general, the stretching ratio is 1.1 to 3.0 times, and preferably 1.2 to 1.5 times. The stretching temperature is generally in the range of Tg of resin composing the film to Tg+50° C., and preferably in the range of Tg to Tg+50° C.

The stretching is preferably carried out under a controlled uniform temperature distribution in the longitudinal or width direction. The temperature is preferably within ±2° C., more preferably within ±1° C., and particularly preferably ±0.5° C.

In the case where the film-shaped resin base material prepared in the above method is used as an optical film, the film may be contracted in the longitudinal or width direction for the purpose of controlling retardation or decreasing in the rate of size change of the aforesaid optical film.

In order to contract in the longitudinal direction, there is a method for contracting the film by, for example, relaxing in the longitudinal direction by temporarily clipping out the width stretching, or by gradually narrowing gaps between neighboring clips of the lateral stretching machine.

Uniformity of the slow axis direction is also important, and the angle with respect to the film width direction is preferably in the range of −5° to +5°, more preferably in the range of −1° to +1°, particularly preferably in the range of −0.5° to +0.5°, and particularly preferably in the range of −0.1° to +0.1°. This dispersion can be achieved by optimizing the stretching conditions.

The film-shaped resin base material relating to the present invention is preferably a long-size film, whose length specifically indicates about 100 m to about 5,000 m, and it is usually provided in a roll shape. Further, the film width is preferably 1.3 to 4 m, and more preferably 1.4 to 2 m.

The film thickness of the film-shaped resin base material relating to the present invention is not particularly limited, and is preferably changed according to its purpose. For example, in the case of using it for a polarizing plate protection film, the film thickness is preferably 20 to 200 μm, more preferably 25 to 150 μm, and particularly preferably 30 to 120 μm.

<Manufacturing Apparatus of Resin Base Material>

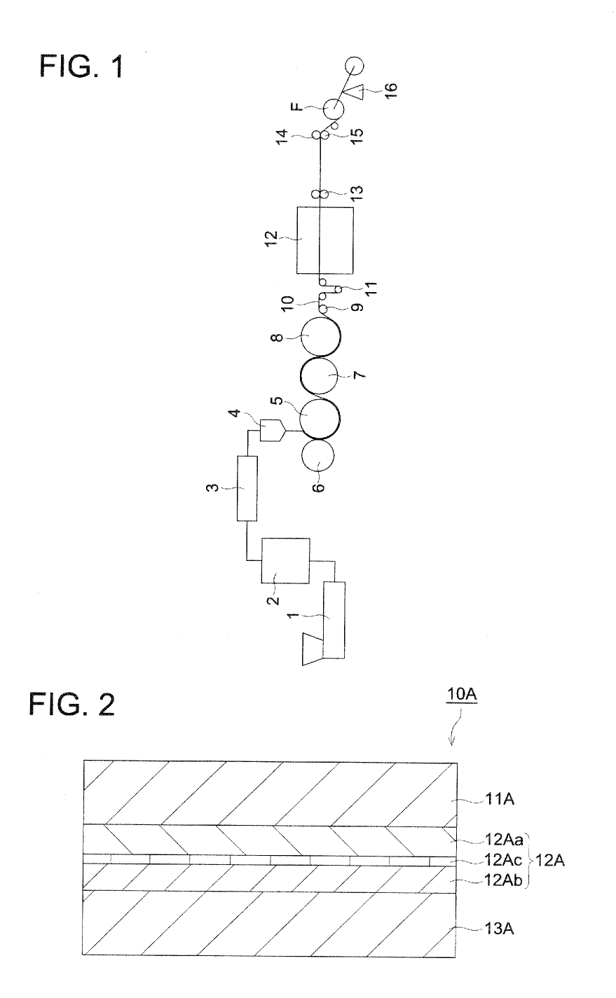

FIG. 1 is a schematic flow sheet showing an entire composition of one example of the manufacturing apparatus of resin base material relating to the present invention. In FIG. 1, the method for manufacturing the resin base material is performed in a manner that film materials such as thermoplastic resin are mixed, and the mixture is melt-extruded from casting die 4 onto first cooling roll 5 using extruder 1. Then, the extruded material is brought into contact with the outer surface of the first cooling roll 5, and at the same time, brought into contact with outer surfaces of a total of three cooling rolls including second cooling roll 7, and third cooling roll 8 one by one, to make the material cooled down and solidified into film 10. Next, film 10 peeled by peeling roll 9 is stretched in the width direction with both ends of the film gripped by stretching apparatus 12, and the stretched film is wound by winding apparatus 16. In order to correct flatness, provided is touch roll 6 pressing a molten film sandwiched between touch roll 6 and the surface of first cooling roll 5. Touch roll 6 has an elastic surface and forms a nip between it and first cooling roll 5.

In the present invention, the manufacturing apparatus is preferably provided with an apparatus which automatically cleans the belt and the rollers. The cleaning apparatus is not particularly limited, and includes, for example, a method for nipping with rollers such as a brushing roller, a water absorption roller, an adhesive roller, a wiping roller; an air-blow method blowing cleaning air; an incineration equipment using a laser; or a combination thereof.

In the case of a method for nipping with cleaning rollers, the large cleaning effect is obtained by differentiating belt linear velocity and roller linear velocity.

(Back Sheet for Solar Cell Module)

In the present invention, a back sheet for a solar cell module of various modes can be manufactured using the aforementioned moisture-proof film of the present invention.

Hereinafter, typical examples will be described, but the invention is not limited to them.

Back sheet 10A for a solar cell module shown in FIG. 2 is structured by laminating inner surface base material 11A and outer surface base material 13A through barrier layers 12A.

Barrier layer 12A is composed of a structure in which first barrier layer 12Aa composed of an aluminum foil arranged on the inner surface base material 11A side and second barrier layer 12Ab composed of a resin film having barrier properties arranged on the outer surface base material 13A side are laminated through, for example, two-liquid reaction type polyurethane resin base adhesive 12Ac.

The aluminum foil of about 5 μm to about 50 μm in thickness composing first barrier layer 12Aa is appropriately used.

Since the barrier property of the aluminum foil is about 0 g/m² day, prevention of degradation of the aluminum foil and longer life thereof directly means prevention of the penetration of water vapor into the solar cell module.

As the resin film composing second barrier layer 12Ab, preferably used is a resin base material (a film) having barrier properties, such as a polyester film of about 5 μm to about 50 μm in thickness, and an ethylene/vinyl alcohol copolymer (EVOH) of about 10 μm to about 50 μm in thickness.

As an inorganic compound composing the moisture-proof layer arranged on the surface of second barrier layer 12Ab, preferably used are silicon oxide, aluminum oxide, magnesium oxide, or a mixture thereof. The thickness of the moisture-proof layer is preferably in the range of 5 to 100 nm.

First barrier layer 12Aa and second barrier layer 12Ab are pasted together with two-liquid reaction type polyurethane resin based adhesive 12Ac by a dry laminate method to make barrier layer 12A. Other than the polyurethane resin based adhesive, a polyester resin based adhesive or a polyetheracryl resin based adhesive may be used.

With barrier layer 12A having a structure described above, barrier layer 12A is allowed to have the highest level barrier properties against oxygen and water vapor due to the aluminum foil of first barrier layer 12Aa, and oxygen and water vapor which come in contact with the aluminum foil in the back sheet are cut off due to an action of second barrier layer 12Ab, and thereby, degradation due to oxidation or hydrolysis is prevented even after a long elapsed time, and the barrier properties of the aluminum foil can be maintained for a long period of time.

Since a plastic film is extremely superior to the aluminum foil with regard to oxidation resistance and hydrolysis resistance, it is preferable to use the plastic film with such structure.

As inner surface base material 11A and outer surface base material 13A, the above resin base material can be preferably used.

Since the combination of these and the thickness influence the insulation properties necessary for the back sheet, it is necessary to separately select the combination of materials and thicknesses which are required with each specification, but, in general, it is preferable that the thickness is about 20 μm to about 50 μm if fluorine-based base material is used, and about 50 μm to about 250 μm if polyester base material is used. Inner surface base material 11A and outer surface base material 13A may be identical or different from each other.

Pasting together of inner surface base material 11A with barrier layer 12A and of barrier layer 2A with outer surface base material 13A can be performed by making inner surface base material 11A and first barrier layer 12Aa face with each other and by making second barrier layer 12Ab and outer surface base material 13A face with each other and then by applying a dry laminate method using two liquids reaction type polyurethane resin based adhesive 12Ac in the same manner that first barrier layer 12Aa and second barrier layer 12Ab are pasted together by a dry laminate method using two liquids reaction type polyurethane resin based adhesive 12Ac.

(Solar Cell Module)

The moisture-proof film of the present invention is applicable to the various modes of the solar cell module.

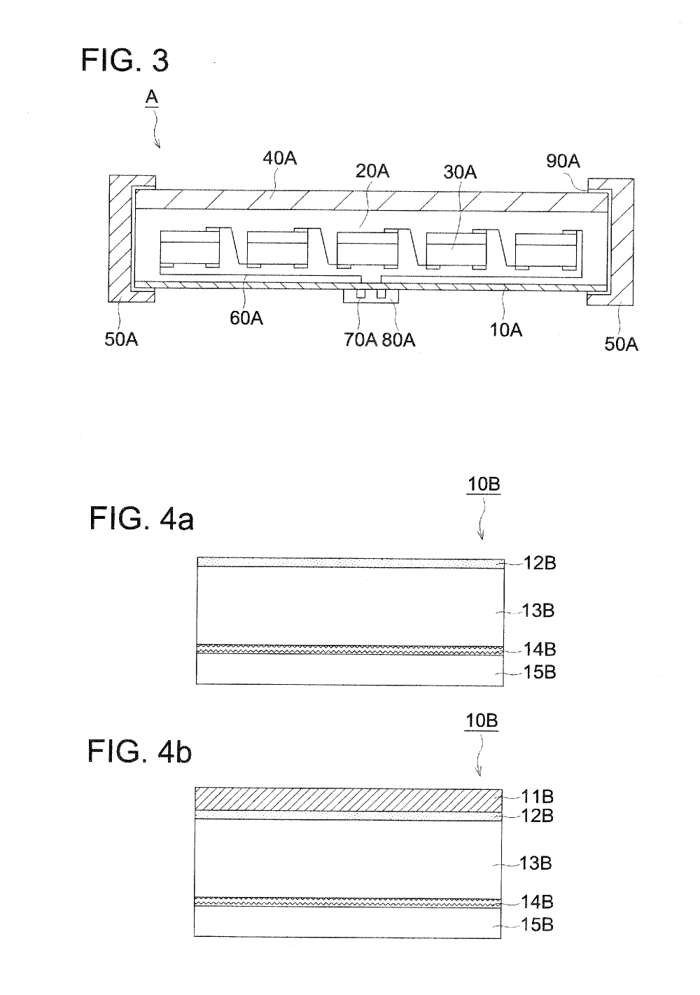

FIG. 3 schematically shows the solar cell module manufactured by using the moisture-proof film of the present invention as hack sheet 10A, and, in the figure, 20A, 30A, 40A, 50A, 60A, 70A, 80A and 90A show a filler (EVA), a solar cell element, a front glass, an aluminum frame, a lead wire, a terminal, a terminal box and a sealing material (butyl rubber) respectively.

As the solar cell element, the various modes of element are usable. For example, usable is, as disclosed in Japanese Patent Application No. 2004-2261, a mode of a solar cell element in which a light transmissive conductive film, a photoelectric conversion film, a rear surface electrode film, all of which film have a texture structure, are successively laminated on a light transmissive insulating substrate, and at the same time, a portion, where the aforesaid photoelectric conversion film and a rear surface electrode film are lacking is arranged, and a light reflective insulating film is arranged on the aforesaid lacking portion.

Hereinafter, the main constitutional elements of the solar cell module will be described.

<Light Reflective Insulating Film>

The term “light reflective insulating film” means an insulating film having a characteristic of reflecting an incident light and introducing the reflected light to the photoelectric conversion film, and any organic or inorganic film can be used without limitation as long as the film has such a characteristic. The use of a film, as the light reflective insulating film, having reflection spectra of reflecting the entire range or a part of the range of wavelengths for which the photoelectric conversion film has the sensitivity, is a preferable mode from a view point of improving usage efficiency of incident light.

For example, in the case of using silicon as the photoelectric conversion film, the light reflective insulating film, which reflects the entire or a part of light of wavelength of 1,000 nm or less which is the light absorption range of silicon is preferably used. Further, in the case of using sun light as a light source, since sun light has a large emission spectrum in the visible light region of 400 to 700 nm, a colored film having reflection spectra of wavelength of the above region is preferable. In particular, a white film is more preferable from a view point of reflecting the most light of wavelength of the visible light region.

The method for forming the light reflective insulating film is not particularly limited, and the film can be formed by, for example, attaching an organic substance in a thin film form or an organic substance onto a necessary part, or by applying organic or inorganic paints onto a necessary part.

The film thickness of the light reflective insulating film is not particularly limited, but 0.01 to 100 μm is preferable from a view point of light reflection intensity, prevention of film peeling, or the like.

<Photoelectric Conversion Film>

The term “photoelectric conversion film” means a film having a characteristic of converting light energy to electric energy, and any organic or inorganic film can be used without limitation as long as the film has such characteristic. As the photoelectric conversion film used for the solar cell, amorphous silicon, polycrystalline silicon, or the like is generally used.

The film thickness of the photoelectric conversion film is not particularly limited, but 0.2 to 10 μm is preferable from a view point of photoelectric conversion efficiency.

<Light Transmissive Conductive Film>

The term “light transmissive conductive film” means a light transmissive electrode arranged on a light incident side of the photoelectric conversion film to take an electric current generated at the photoelectric conversion film, and is not particularly limited as long as the film has such a characteristic, but indium tin oxide (ITO), tin oxide (SnO₂), or the like is generally used.

The film thickness of the light transmissive conductive film is not particularly limited, but 0.1 to 2 μm is preferable from a view point of photoelectric conversion efficiency.

<Rear Surface Electrode Film>

The term “rear surface electrode film” means an electrode arranged on a rear surface of the photoelectric conversion film (a reverse side of a light incident side) to take an electric current generated at the photoelectric conversion film, a metal electrode is generally used since the electrode does not need to transmit light. As the metal electrode, silver, aluminum, or the like of about 0.1 μm to about 1 μm is generally used.

<Light Reflective Insulating Film>

The term “light transmissive insulating film” means an insulating film having a characteristic of transmitting incident light, and need to have a lower refractive index than that of light transmissive conductive film. This is because, with a higher refractive index than that of light transmissive conductive film, the incident light comes through the light transmissive insulating film. This is because in the light transmissive insulating film, if its refractive index is lower than that of the light transmissive insulating film, the incident light is trapped in the light transmissive conductive film and the light transmissive insulating substrate due to a texture structure formed at an interface between the light transmissive conductive film and the light transmissive insulating film. Any organic or inorganic film can be used without limitation as long as the film has such a characteristic. A transparent film and a semitransparent film are included in the light transmissive insulating film.

In the present invention, in the case of using light transmissive insulating film having the refractive index lower than that of light transmissive conductive film, it is also preferable to further arrange a reflection film on the surface of the aforesaid light transmissive insulating film from a view point of further reducing light leakage. This reflection film is sufficient as long as the film has a characteristic to reflect the incident light and introduce the reflected light to the photoelectric conversion film, and includes not only the light reflective insulating film but the light reflective conductive film or the like. Especially, when using a film having the refractive index equal to that of light transmissive conductive film, the reflection film is required to prevent incident light leakage.

The term “texture structure” means that the surface shape of the light transmissive conductive film, photoelectric conversion film and the rear surface electrode film adopts a structure in which many minute pyramids of about 1 μm to about 10 μm are collected. It is called the texture structure because it looks like a textile structure. When the surface for incident light has the texture structure, the surface reduces the reflected light, and when the surface for outgoing light has the texture structure, the angle between the re-incident light and the surface of light transmissive insulating substrate becomes smaller because of light reflection on the texture surface, to reduce the outgoing light from the surface of light transmissive insulating substrate, which is the initial surface of incident light, and thereby the texture structure has a function to trap the incident light in the light transmissive conductive film and photoelectric conversion film.

### EXAMPLES

Hereinafter the present invention will be specifically described using examples and comparative examples.

### Comparative Example 1

### Formation Step of Moisture-proof Layer by Vacuum Vapor Deposition

As the base material, a biaxially drawn polyester film (a polyethylene terephthalate film of 100 μm in thickness) was used. Next, using a take-up type vacuum deposition equipment, evacuation was carried out until the attained degree of vacuum of the chamber reached 3.0×10⁻⁵ torr (4.0×10⁻³ Pa), after which oxygen gas was introduced near the coating drum with maintaining the pressure in the chamber at 3.0×10⁻⁴ torr (4.0×10⁻² Pa), and then, silicon monoxide as an evaporation source was heated with about 10 kW in power via a pierce-type electron gun and vapor-deposited, whereby a moisture-proof layer of 2 μm in thickness composed of silicon oxide was formed on the polyester film running on a coating drum at a rate of 120 m/min to prepare the sample of Comparative Example 1.

### Comparative Example 2

### Formation Step of Moisture-proof Layer using Sol made from Organic Metal Compound

As a sol solution made from an organic metal compound, 004 mol of tetraethoxysilane (manufactured by Wako Pure Chemical Industries, Ltd.) was weighed in a polypropylene beaker. To the weighed compound, 0.25 mol of ethyl alcohol was added while stirring, which was then stirred for 10 minutes using a magnetic stirrer. Further, 0.24 mol of pure water was added and the mixture was stirred for 10 minutes, after which 1 ml of HCl of 1 mol/L was added to prepare sol solution-1. On one side of a biaxially drawn polyester film (a polyethylene terephthalate film of 100 μm in thickness), above sol solution-1 was applied as bar coating so that the dried film thickness became 2 μm, which was heat-dried using a dry oven at 150° C. for 30 minutes to prepare the sample of Comparative Example 2.

### Comparative Example 3

400 g of pure water was added to 1 L stainless pot, and 600 g of silicon oxide (average particle diameter of 1.3 μm) was added to the water using ULTRA-TURRAX T25 digital (manufactured by IKA Co.), at 6,000 rpm over 5 minutes, and then, dispersion was carried out for 30 minutes. After that, 1,000 g of MEK was added to the dispersion, and then, an operation of eliminating solvent was repeated three times under a reduced pressure of 2.0×10² torr (2.7×10⁴ Pa) and at bath temperature of 40° C. using an evaporator until the residual mass reached 800 g, and finally, 200 g of MEK was added to make the total mass equal to 1,000 g to prepare dispersion-A. On one side of a biaxially drawn polyester film (a polyethylene terephthalate film of 100 μm in thickness), above dispersion-A was applied as bar coating so that the dried film thickness became 2 μm, which was then heat-dried using a dry oven at 150° C. for 30 minutes to prepare the sample of Comparative Example 3.

### Example 1

400 g of pure water was added to 1 L stainless pot, and 600 g of silicon oxide (manufactured by DEMO KAGAKU KOGYO KABUSHIKI KAISHA, trade name: SFP-30M, average particle diameter of 700 nm) was added to the water using ULTRA-TURRAX T25 digital (manufactured by HCA Co.), at 6,000 rpm over 5 minutes, and then, dispersion was carried out for 30 minutes. After that, 1,000 g of MEK was added to the dispersion, and then, an operation of eliminating solvent was repeated three times under a reduced pressure of 2.0×10² torr (2.7×10⁴ Pa) and at bath temperature of 40° C. using an evaporator until the residual mass reached 800 g, and finally, 200 g of MEK was added to make the total mass equal to 1,000 g to prepare dispersion-1. Next, 20 parts by mass of tetraethoxy silane (Si(C₂H₅O)₄) and 80 parts by mass of phenyltriethoxy silane (C₆H₅Si(OC₂H₅)₃) were mixed into 100 parts by mass of ethyl alcohol, which mixture was then allowed to react using a formic acid as a catalyst to prepare an acid solution. Subsequently, the acid solution was neutralized by triethylamine ((C₂H₅)₃N) to obtain a neutralized solution. Then, the solvent in the neutralized solution was substituted with methylethyl ketone, to prepare resin solution-1 having a concentration of nonvolatile resin of 60% and the viscosity of 400 mPa·s. 30 g of dispersion-1 and 70 g of resin solution-1 were mixed, and then the mixed dispersion was applied on one side of a biaxially drawn polyester film (a polyethylene terephthalate film of 100 μm in thickness) as bar coating so that the dried film thickness became 2 μm, which was then heat-dried using a dry oven at 150° C. for 30 minutes to prepare the sample of Example 1.

The fact that a reaction product of the above alkoxy silane has a polysiloxane structure was confirmed by a Si—NMR measurement.

### Example 2

With entirely the same operations as dispersion-1 except that the silicon oxide was changed to SFP-20M, trade name, manufactured by DENKI KAGAKU KOGYO KABUSHIKI KAISHA (particle diameter of 300 nm), dispersion-2 was prepared. Further, with the similar operations to Example 1, the sample of Example 2 was prepared.

### Example 3

With entirely the same operations as dispersion-1 except that silicon oxide was changed to sicastar, trade name, manufactured by COREFRONT Corp. (particle diameter of 70 nm), dispersion-3 was prepared. Further, with the similar operations to Example 1, the sample of Example 3 was prepared.

### Example 4

Dispersion in water of aluminum oxide (manufactured by TETSUTANI & Co., Ltd., trade name of NANOBYK-3600, average particle diameter of 40 nm) and 1,000 g of MEK were added into 1 L stainless steel pot, and then, an operation of eliminating solvent was repeated three times under a reduced pressure of 2.0×10² torr (2.7×10⁴ Pa) and at bath temperature of 40° C. using an evaporator until the residual mass reached 800 g, and finally, 200 g of MEK was added to make the total mass equal to 1,000 g to prepare dispersion-4.30 g of dispersion-4 and 70 g of resin solution-1 were mixed, and then the mixture was applied on one side of a biaxially drawn polyester film (a polyethylene terephthalate film of 100 μm in thickness) as bar coating so that the dried film thickness became 2 μm, which was then heat-dried using a dry oven at 150° C. for 30 minutes to prepare the sample of Example 4.

### Example 5

With entirely the same operations as dispersion-1 except that silicon oxide was changed to titanium oxide having average particle diameter of 50 nm, dispersion-5 was prepared. Further, with the similar operations to Example 1, the sample of Example 5 was prepared.

### Example 6

30 g of dispersion-3 and 70 g of resin solution-1 were mixed, and then the mixture was applied on one side of a biaxially drawn polyester film (a polyethylene terephthalate film of 100 μm in thickness) as bar coating so that the dried film thickness became 2 μm, which was then heat-dried using a dry oven at 70° C. for 20 minutes. After that, using a near infrared dryer (paint dryer PDH1000, manufactured by Nihon Dennetsu Co., Ltd.), with an output of 1 kW, infrared irradiation for 0.5 sec. at a distance of 50 cm from a coated surface was repeated for ten times, to prepare the sample of Example 6.

### Example 7

30 g of dispersion-1 and 70 g of resin solution-1 were mixed, and then the mixture was applied on one side of a biaxially drawn polyester film (a polyethylene terephthalate film of 100 μm in thickness) as bar coating so that the dried film thickness became 2 μm, which was then heat-dried using a dry oven at 40° C. for 120 minutes to prepare the sample of Example 7.

[Evaluation]

The oxygen permeation rate and the water vapor permeation rate on each sample prepared above were determined by the method below, and the results were evaluated.

<Oxygen Permeation Rate>

The oxygen permeation rate is a value determined under conditions of measuring temperature of 23° C., and humidity of 90% RH, using the oxygen gas permeation rate measuring apparatus (trade name: OX-TRAN 2/20, manufactured by Modern Control, Inc.). The above water vapor permeation rate is a value determined under conditions of measuring temperature of 37.8° C., and humidity of 100% RH, using the water vapor permeation rate measuring apparatus (trade name: PERMATRAN-W 3/31, manufactured by Modern Control, Inc.).

<Water Vapor Permeation Rate>

The water vapor permeation rate is a value which was measured under conditions of measuring temperature of 40.0° C., and humidity of 90% RH, using the water vapor permeation rate measuring apparatus (trade name: PERMATRAN-W 3/31, manufactured by Modern Control, Inc).

The evaluation results of the characteristics of moisture-proof films obtained above are shown in Table 1.

TABLE 1

| | Inorganic Particles | | Oxygen | Water Vapor |
|---|---|---|---|---|
| | | Average | Permeation | Permeation |
| | Com- | Particle | Rate (ml/m² · | Rate (g/m² · |
| Sample | position | Diameter (μm) | day · atm) | day) |
| Comparative | — | — | 0.7 | 0.8 |
| Example 1 | | | | |
| Comparative | — | — | 3.0 | 2.5 |
| Example 2 | | | | |
| Comparative | SiO₂ | 1.3 | 1.2 | 1.1 |
| Example 3 | | | | |
| Example 1 | SiO₂ | 0.7 | 0.7 | 0.6 |
| Example 2 | SiO₂ | 0.3 | 0.5 | 0.4 |
| Example 3 | SiO₂ | 0.07 | 0.2 | 0.1 |
| Example 4 | Al₂O₃ | 0.04 | 0.3 | 0.2 |
| Example 5 | TiO₂ | 0.05 | 0.2 | 0.3 |
| Example 6 | SiO₂ | 0.07 | 0.1 | 0.05 |
| Example 7 | SiO₂ | 0.7 | 0.9 | 0.8 |

As is clearly shown from the results shown in Table 1, it is found that the moisture-proof films relating to the present invention are excellent in barrier property against water vapor or oxygen. With regard to Comparative Example 2, since the resin film was contracted and deformed by heating, it was impossible to use it as the moisture-proof film.

### Examples 8 to 14

Two-liquid reaction type polyurethane resin based adhesive 14B was applied onto the outer surface side of resin base material 13B of the moisture-proof film prepared in Example 1 (the amount of coating is 5 g/m²), and then, a white polyethylene terephthalate film of 50 μm in thickness, which is used as inner surface base material 15B, was pasted to prepare aback sheet for a solar cell of Example 8a composed of the layer structure of FIG. 4a.

Using the back sheet of Example 8a, a glass, a filler (EVA), a solar cell element a filler (EVA) and the back sheet were superposed as shown in FIG. 2, which were then laminated by vacuum heating at 150° C. and 1.0 torr (1.3×10² Pa) for 30 minutes to prepare a solar cell module of Example 8b.

In the similar manner, with regard to the moisture-proof films prepared in Examples 2 to 7, back sheets for solar cell of Examples 9a to 14a and solar cell modules of Examples 9b to 14b were prepared.

Water vapor permeability of the back sheets of Examples 8a to 14a and the solar cell modules of Examples 8b to 14b prepared in such ways, after each sample was kept under an environment of 85° C. and 85% RH for 0, 1000, 2000 and 3000 hours, was determined according to the method of JIS K7129. The results are shown in Table 2.

TABLE 2
Water Vapor Permeability (g/m² · day)

| | Elapsed Time (h) | | | |
|---|---|---|---|---|
| Sample | 0 | 1000 | 2000 | 3000 |
| Example 8a | 0 | 0.2 | 0.4 | 0.7 |
| Example 9a | 0 | 0.15 | 0.3 | 0.5 |
| Example 10a | 0 | 0.07 | 0.1 | 0.12 |
| Example 11a | 0 | 0.09 | 0.11 | 0.13 |
| Example 12a | 0 | 0.08 | 0.09 | 0.11 |
| Example 13a | 0 | 0.03 | 0.05 | 0.06 |
| Example 14a | 0 | 0.3 | 0.6 | 0.9 |

As is clearly shown from the results shown in Table 2, it is found that the back sheets relating to the present invention are excellent in barrier property against water vapor.

The solar cell modules of Examples 8b to 14b, which had been kept under an environment of 85° C. and 85% RH for 3000 hours, showed similar power generation efficiency (15 to 18%) to those before being kept under the environment.

### DESCRIPTIONS OF ALPHANUMERIC DESIGNATIONS

1. Extruder
2. Filter
3. Static mixer
4. Flow casting die
5. Rotational support (First cooling roll)
6. Sandwiching press rotating body (Touch roll)
7. Rotational support (Second cooling roll)
8. Rotational support (Third cooling roll)
9. Peeling roll
10. Film
11, 13 and 14. Conveying roll
12. Stretching machine
15. Slitter
16. Winding apparatus
F. Film-shaped resin base material relating to the present invention
A. Solar cell module
10A. Back sheet
11A. Inner surface base material
12A. Barrier layer
12Aa. First barrier layer
12Ab. Second barrier layer
12Ac. Adhesive layer
13A. Outer surface base material
20A. Filler
30A. Solar cell element
40A. Front glass
50A. Aluminum frame
60A. Lead wire
70A. Terminal
80A. Terminal box
90A. Sealing material
10B. Back sheet for solar cell
11B. Synthetic resin layer
12B. Moisture-proof layer
1313. Resin base material
14B. Adhesion layer
15B. Inner surface base material

1. A moisture-proof film in which a moisture-proof layer is arranged on a resin base material,
wherein the moisture-proof layer is composed of a coating film including an inorganic oxide film containing inorganic oxide particles having an average particle diameter of 1 nm or more and 1 μm or less.

2. The moisture-proof film of claim 1,
wherein the inorganic oxide particles include at least one compound among silicon oxide, aluminum oxide, zinc oxide, titanium oxide, and zirconium oxide.

3. A manufacturing method of a moisture-proof film for manufacturing the moisture-proof film of claim 1, the method comprising the steps of:
forming a coating film by applying a compound having a polysiloxane structure and a dispersion containing inorganic oxide particles onto a resin base material; and
forming an inorganic oxide film containing inorganic oxide particles by heating the coating film at a heating temperature of 50° C. or more and 200° C. or less.

4. A back sheet for a solar cell module,
wherein the moisture-proof film of claim 1 is used.

5. A solar cell module,
wherein the moisture-proof film of claim 1 is used for a back sheet.

6. A manufacturing method of a moisture-proof film for manufacturing the moisture-proof film of claim 2, the method comprising the steps of:
forming a coating film by applying a compound having a polysiloxane structure and a dispersion containing inorganic oxide particles onto a resin base material; and
forming an inorganic oxide film containing inorganic oxide particles by heating the coating film at a heating temperature of 50° C. or more and 200° C. or less.

7. A back sheet for a solar cell module,
wherein the moisture-proof film of claim 2 is used.

8. A solar cell module,
wherein the moisture-proof film of claim 2 is used for a back sheet.
